(19) United States
(12) Patent Application Publication
(10) Pub. No.: US 2013/0207070 A1
(43) Pub. Date: Aug. 15, 2013

(54) Nanocomposite Material And Its Use In Optoelectronics

(71) Applicant: Etienne Quesnel, Meylan (FR)

(72) Inventor: Etienne Quesnel, Meylan (FR)

(73) Assignee: Commissariat A L'Energie Atomique Et Aux Energies Alternatives, Paris (FR)

(21) Appl. No.: 13/702,635

(22) PCT Filed: Jun. 7, 2011
(86) PCT No.: PCT/IB11/52476

§ 371 Date: Feb. 5, 2013

(30) Foreign Application Priority Data
Jun. 8, 2010 (FR) 10 02410

(51) Int. Cl. H01L 29/15; H01L 21/02

(52) U.S. Cl. CPC H01L 29/151; H01L 21/02601
USPC 257/9; 438/478

(57) ABSTRACT

Material comprising a matrix made of semiconducting or insulating, transparent material in which core/shell type nanoparticles are dispersed, the core of which consists of a semiconductor and the shell of which is formed from a material chosen from the oxides TiO₂ and/or CeO₂. These nanocomposite materials may especially be used as optoelectronic absorbers.

The invention relates to novel nanocomposites, to a process for manufacturing them and to their uses, especially as optoelectronic absorbers. In particular, the material of the invention may be used to manufacture photovoltaic cells or any type of optoelectronic system that uses an absorbent material to convert photons into an electrical current.

The invention relates to the field of optoelectronic components, i.e. to electronic components that emit light or interact with light.

A photovoltaic cell is an electronic component that, when exposed to light (photons), generates electricity. The current obtained depends on the incident light. The electricity produced depends on the illumination conditions.

Photovoltaic cells are often combined in solar photovoltaic modules or solar panels, their number varying depending on the required electrical power.

Photovoltaic cells are most commonly made of semiconductors, mainly semiconductors based on silicon (Si) and sometimes other semiconductors such as copper indium selenide (CuIn(Se)₂ or CuInGa(Se)₂) or cadmium telluride (CdTe). These cells generally take the form of thin sheets, the width of which is about ten centimeters per side, placed between two metal contacts, the resulting device being about one millimeter in thickness. A photovoltaic cell may consist of a number of materials combined in various configurations. The expression “active material” will be used to denote the absorbent material that transforms light into electron/hole carriers.

At the present time three generations of photovoltaic cells are known:

the active material of the first generation is based on single-crystal silicon or polysilicon; the second generation was developed based on thin films (active material: amorphous, polymorphous, micro-crystalline silicon; CIGS; CdTe, etc.); and the third generation was derived directly from the second but includes advanced concepts for collecting light.

These concepts aim to increase the amount of light collected by way of various methods that may be classed as follows:

(i) increasing optical scattering of the incident light;

(ii) increasing the optical absorption of the active material by generating a plasmonic effect in this film of material;

or even

(iii) matching the active material to the solar spectrum.

In this third approach, the active material is often matched to the solar spectrum using multi-junctions, each junction being intended to absorb a particular part of the solar spectrum. This is the case for example of III-V double- or triple junctions (King et al., Applied Physics Letters, 90, (2007), p 183516) the combination of which results in most of the solar spectrum being absorbed. Each material of the multi junction has a particular bandgap and absorbs in a given spectral range.

To meet the same objective of matching the active material to the solar spectrum, another approach consists in using semiconductor nanoparticles the bandgap of which depends on their size to modulate the spectral ranges absorbed. Semiconductor nanoparticles that are smaller than 5 nm in diameter generally have this property. This is especially the case for silicon nanoparticles, the bandgap of which increases from 1.1 to 2.5 eV when the size of the crystallites decreases from 5 nm to 3 nm. In general, so that they can be used to manufacture optoelectronic components, these nanoparticles are embedded in a dielectric matrix so as to form a nanocomposite. If a multilayer comprising various nanocomposites, each composite containing nanoparticles of a given size, is used, a multi junction photovoltaic cell is created that interacts with all the photons in the solar spectrum, whatever their energies.

The use of silicon nanoparticles for photovoltaic applications was suggested a few years ago by M. Green et al., “All-silicon tandem cells based on “artificial” semiconductors synthesized using silicon quantum dots in a dielectric matrix”, Proceedings of the 20th European Photovoltaic Solar Energy Conference, Barcelona, June 2005, p. 3”. These silicon nanoparticles are called “quantum dots”. Generally, the technique used to manufacture these nanocomposites comprises vacuum deposition of a film containing excess silicon, such as SiOₓ where x<2, SiC_{y} where y<1 or even SiN_{z} where z<4/3. Annealing these compounds at a high temperature (1100° C.) causes the excess silicon to precipitate and form silicon nanocrystals. A variant of this technique consists in depositing multilayers of, in alternation, very thin (typically 1-5 nm in thickness) dielectric and pure-silicon (A. K. Dutta, Applied Physics Letters; 68, 9, (1996), p. 1189) or SiO (Zacharias et al. Applied Physics Letters, 80 (2002), p. 661) films and annealing what is produced. These techniques therefore allow a nanocomposite based on silicon nanoparticles or nanocrystals (referred to by the general term Si quantum dots) to be produced, these nanoparticles or nanocrystals being embedded in a silica matrix.

Similar techniques have been used to generate germanium nanocrystals, most often by codeposition (A. K. Dutta, Applied Physics Letters, 68, 9, (1996), p 1189; T. P. Leervad Pedersen et al., Applied Physics A, 81, (2005), p 1591-93) of an Si₍₁₋ₓ₎Geₓ compound using a CVD or PVD (J. Skov Jensen et al., Applied Physics A, 83, (2006), p 41-8) technique, followed by an annealing step, commonly at a temperature between 800 and 1100° C. for 0.5 to 2 hours. The optoelectronic behavior of such a composite is the result of charge carriers (electrons or holes) being photogenerated in the nanoparticles and conducted through the matrix.

If the matrix is made of silica, this conduction only takes place if the nanoparticles make contact with one another or are very near to one another. To improve this aspect of electrical charge transfer, one of the solutions proposed recently consists in embedding the nanoparticles in a semiconductor (SiC) or conductive-oxide (ZnO, ITO, In₂O₃) matrix. These solutions are currently being studied and their feasibility remains to be demonstrated. In addition to the deposition technologies used, it is possible, by analyzing the thermodynamic properties of such a system, to predict that it will be difficult to control the interface between the nanoparticle and the matrix in the case where conductive oxides are used.

These materials are based on a transparent matrix made of conductive oxides such as In₂O₃, ITO (In, Sn, O) or ZnO, whether doped or not. Semiconductor quantum dots or nanoparticles are inserted into this matrix, these dots or nanoparticles absorbing solar light and generating electron/hole pairs. The diameters of these nanoparticles vary from 1 to 30 nm and preferably from 1 to 15 nm in order to preserve a quantum confinement effect. The materials from which these nanoparticles are made are most commonly covalent semiconductors such as Si or Ge or their alloy Si₍₁₋ₓ₎Geₓ. It is also possible to use what are called “II-VI” ionic materials such as CdTe, CdSe, ZnTe and ZnSe, or even “III-V” materials such as GaP, GaAs and InSb, etc. In any case, the ideal structure that it would be desired to produce is the structure shown in FIG. 1, in which (1.1) represents the transparent conductive matrix and (1.2) represents the silicon nanocrystals.

If only the use of covalent semiconductors is considered, in a conventional technology in which Si, Ge or SiGe nanoparticles are precipitated in an oxide matrix, an anneal at a temperature of several hundred degrees is required. This anneal is moreover indispensible if semiconductor nanocrystals that are free from electronic defects (traps that cause charge-carrier recombination) and that have a carrier mobility that is acceptable for photovoltaic applications are to be produced. Under these conditions, and due to the thermodynamic properties of the constituents of the nanocomposites thus formed, it is inevitable that a composite formed from nanocrystals of Si or Ge or Si₍₁₋ₓ₎Geₓ surrounded by an insulating barrier of native oxide, respectively SiO₂, GeO₂ or a mixture of the two, will be deposited. This result is shown in FIG. 2. In FIG. 2, (2.1) represents the transparent conductive matrix, (2.2) represents the silicon nanocrystals, and (2.3) represents SiO₂.

This oxidation results from a thermodynamic equilibrium between phases, the presence of which is often evaluated using Ellingham diagrams. FIG. 3 shows these diagrams for the elements Si, Ge, In and Zn. The diagram may be interpreted in the following way: if germanium is placed in ZnO or in indium oxide or ITO, the germanium will not be oxidized at the expense of the other oxides (the oxidization curve of Ge is above the oxidization curves of indium and zinc). If the temperature exceeds 700-800° C., germanium may oxidize in an ITO matrix.

In contrast, if silicon is placed in conductive oxides based on In₂O₃, ITO (In, Sn, O) or ZnO, it will oxidize whatever the temperature of the annealing process.

The major drawback of current solutions, in addition to the electrical transport problems that they may cause, is that when the quantum dot oxidizes semiconductor material is consumed and therefore the size of the quantum dot decreases. However, as was mentioned above, it is precisely via control of the size of the nanoparticles or nanocrystals that the desired properties are obtained.

Controlling the crystallization temperature of the quantum dot (which depends on its size) and controlling its size, knowing that the latter depends on the oxidation kinetics and therefore the temperature, is therefore extremely difficult.

The present invention overcomes these problems by using novel materials based on surface-functionalized nanoparticles that are dispersed in a matrix, this functionalization allowing the oxidation state of the nanoparticles to be stabilized while promoting transfer of the electrical charge photogenerated in the nanoparticles to the conductive matrix. The invention more particularly relates to a material based on these nanoparticles and to a method for preparing this material.

The first subject of the invention is a material comprising a matrix made of a transparent semiconductor or insulating material in which core/shell nanoparticles are dispersed, the core of which is made of a semiconductor chosen from the covalent semiconductors Si, Ge and SiGe, and ionic II-VI or III-V semiconductors, and the shell of which is made of a material chosen from the oxides TiO₂ and/or CeO₂.

The expression “ionic II-VI or III-V semiconductors” is understood to mean an alloy the components of which are atoms respectively chosen from columns II and VI or columns III and V of the Periodic Table of the Elements.

The expression “semiconductor or insulating material” is also understood to include transparent conductive oxides.

The matrix may especially be made of a material chosen from the oxides, semiconductors or insulators: SiO₂, SiC, SiNₓ (x≦4/3), In₂O₃, ITO (In, Sn, O) or ZnO, whether doped or not. Preferably the matrix is made of a material chosen from: ITO and ZnO.

The nanoparticles are between 1 and 30 nm in size, preferably between 1 and 15 nm in size. They consist of a core that is between 1 and 25 nm in size and a shell. The size of the nanoparticle or of its core is the largest diameter of this object. The shell is preferably between 2 and 4 nm in thickness.

Preferably, in a material of the invention, the nanoparticles each have a core, these cores all being substantially the same size, i.e. the average diameter of the nanoparticle cores is chosen such that at least 90% of the particles in the material have this diameter to within ±20%.

Advantageously, the core is made of a semiconductor chosen from: Si, Ge, Si₍₁₋ₓ₎Geₓ where x is a number and 0.1≦x≦0.9, the ionic materials called the “II-VI's” such as CdTe, CdSe, ZnTe or ZnSe, or the ionic materials called the “III-V's”, such as GaP, GaAs or InSb. Preferably, the core is based on Si, Ge or Si₍₁₋ₓ₎Geₓ.

The shell is made of a material chosen from TiO₂, CeO₂, and their alloys.

The material of the invention is called a nanocomposite, meaning that it has a composite structure (it is made up of at least two separate materials, one forming the matrix and the other the nanoparticles), one of the materials being present in the form of a nanoscale structure.

As in conventional quantum dot systems, the bandgap is adjusted by selecting the size of the particles. Thus it is possible to manufacture a material the bandgap of which is precisely fixed, and superposing films of materials of the invention having different and preset bandgaps makes it possible to obtain a multi junction component that interacts with all the photons in the solar spectrum, whatever their energies.

Advantageously, the concentration of nanoparticles in the matrix is between 1×10¹⁶ cm⁻³ and 1×10¹⁹ cm⁻³.

Therefore, another subject of the invention is an article formed by superposing films of the materials of the invention, which materials were described above.

Advantageously, such an article comprises 1 to 10 films of the material of the invention.

More advantageously, the superposed films of material all comprise matrices made of the same material.

Even more advantageously, the superposed films of material are all based on nanoparticles made of the same material.

Advantageously, each film of material comprises particles of a different size from that of the particles in the other films.

Coating the core with the oxides TiO₂ and CeO₂ (shell materials) prevents the core nanoparticles from oxidizing, whether they are made of Si, Ge, SiGe or another material.

The materials of the present invention have the structure illustrated in FIG. 4. In FIG. 4, (4.1) represents the transparent conductive matrix, (4.3) represents the silicon or germanium nanocrystals forming the core of the nanoparticles, and (4.2) represents the TiO₂ or CeO₂ shell.

The oxides TiO₂ and CeO₂ are stable relative to the semiconductors Si, Ge and SiGe up to very high temperatures, at least 1200° C., as may be seen from the diagram shown in FIG. 5. This is particularly true for Ge. It is also true relative to the main constituent metal elements of II-VI and III-V semiconductors.

Moreover, these TiO₂ and/or CeO₂ layers are also perfectly stable relative to the transparent conductive matrix (oxides based on In or Zn). The same also applies relative to matrices based on Si, such as SiO₂, SiC or SiNₓ matrices.

Therefore, during the annealing phase used to crystallize the nanoparticles, the TiO₂ or CeO₂ layers pump the residual oxygen trapped in the core of the nanoparticles and protect said core from any subsequent oxidation in the matrix.

From the point of view of their electrical properties, electrical conductivity data, although very dependent on the method used to produce the thin oxide film, allow the oxides to be classed in order of decreasing resistivity, namely: SiO₂, CeO₂, TiO₂ then ITO and ZnO. In other words, in the case of nanoparticles with silicon-based cores, a structure according to the invention, as illustrated in FIG. 4, has better charge transport properties than a prior-art structure such as illustrated in FIG. 2.

From the point of view of their optical properties, the oxides TiO₂ and CeO₂, in contrast to SiO₂ for example, have a smaller bandgap (3 eV). Under illumination at blue or ultraviolet wavelengths, these materials become relatively conductive, thereby promoting transport of the charge carriers photogenerated by the nanoparticles and preventing their recombination.

TABLE 1
electrical and optical properties of oxides

| Matrix | SiO₂ | TiO₂ | CeO₂ | ITO | ZnO |
|---|---|---|---|---|---|
| Resistivity | 1 × 10¹⁴ | 1 × 10²-1 × | 1 × 10⁹ | 2 × 10⁻⁴ | 2 × 10⁻⁴ |
| (Ω · cm) | | 10⁵ | | | |
| Bandgap | 9 eV | 3.26 eV | 3.1 eV | 3.8 eV* | 3.3 eV* |

Another subject of the invention is a method for manufacturing the materials that were described above.

The manufacturing method allows core/shell semiconductor particles to be manufactured, the shell being made of TiO₂ and/or CeO₂.

To prevent oxidation of the core, vacuum synthesis techniques are preferred though wet processing may also be used. Three different vacuum processes are provided having the operating modes described below.

According to a first process the following steps are carried out:
producing, in a nanoparticle source, a binary vapor consisting of core atoms and, in a smaller amount (from 5 to 30 mol % shell atoms relative to the number of moles of core atoms), constituent atoms of the shell, i.e. Ti and/or Ce atoms;
forming nanoparticles by condensing the gaseous phase atoms by cooling the vapor;
transferring the nanoparticles thus formed into a deposition chamber;
spraying onto a substrate;
annealing at a temperature ranging from 100° C. to 700° C.; and
depositing the insulator or semiconductor forming the matrix at the same time as or in alternation with the nanoparticles in the same vacuum deposition chamber.

According to one variant, another process allowing the materials of the invention to be obtained comprises the following steps:
depositing in alternation very thin, 0.2 to 5 nm-thick, films of material in the following sequence: matrix material/shell material/core material/shell material/matrix material;
repeating the alternate deposition according to the above sequence 10 to 100 times with the materials of each category remaining the same or changing, the thickness of each material, in particular the thickness of the core material, optionally being varied, until a material having the desired thickness is obtained; and
annealing at a temperature ranging from 800° C. to 1000° C.

The film of shell material has the effect of reducing the deposition atmosphere in the chamber. The anneal causes the core material to precipitate in the form of elongate particles the length of which is perfectly controlled. This core material is protected by the oxidation of the shell material and remains in the semiconductor state. A product such as illustrated in FIG. 7 is obtained. In FIG. 7, the ZnO matrix (7.1) comprises films of silicon nanoparticles (7.2) coated with TiO₂ shells (7.3).

According to another variant, the materials of the invention may be produced using a process that comprises the following steps:
producing, in a nanoparticle source, a binary vapor consisting of core atoms;
forming nanoparticles by condensing the gaseous phase atoms by cooling the vapor;
transferring the nanoparticles thus formed into a deposition chamber;
depositing in alternation very thin, 0.2 to 5 nm-thick, films of material in the following sequence: matrix material/shell material/core nanoparticles/shell material/matrix material; and
annealing at a temperature ranging from 100° C. to 700° C.

This solution allows much better control of the size of the nanoparticles.

The last two variants may be carried out by a chemical vapor deposition (CVD) process.

The advantages of the composite materials of the invention over prior-art materials are the following:
the size of the quantum dots inserted into the matrix is better controlled, and therefore the absorption characteristics of the nanocomposite absorber are better controlled; and
the interface of the quantum dots inserted into the matrix is better controlled and therefore the electrical behavior of the nanocomposite absorber used as a photoelectric generator is better controlled.

The industrial applications of the invention are the following: manufacturing photovoltaic cells; manufacturing optoelectronic detectors or imagers; and manufacturing of optical and/or magnetic substrates for data storage.

### FIGURES

FIG. 1: shows a schematic illustration of a composite material comprising a transparent conductive matrix and silicon nanocrystals.

FIG. 2: shows a schematic illustration of a composite material comprising a transparent conductive matrix and silicon nanocrystals surrounded by SiO₂.

FIG. 3: shows Ellingham diagrams for the elements Si, Ge, In and Zn (after the Handbook of Chemistry and Physics, 74th edition).

FIG. 4: shows a schematic illustration of a material of the invention comprising a transparent conductive material and nanoparticles of silicon or germanium nanocrystals coated with a TiO₂ or CeO₂ shell.

FIG. 5: shows a diagram illustrating the enthalpy of oxidation for the materials Ti, Ce, Si, Ge, Zn and In as a function of temperature (after the Handbook of Chemistry and Physics, 74th edition).

FIG. 6: shows a schematic illustration of a nanoparticle source operating by sputtering.

FIG. 7: shows a schematic illustration of a multilayer material according to the invention.

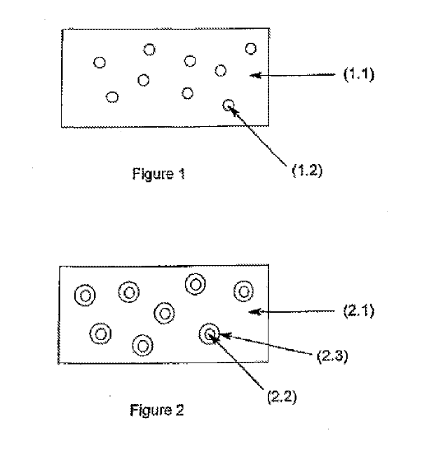

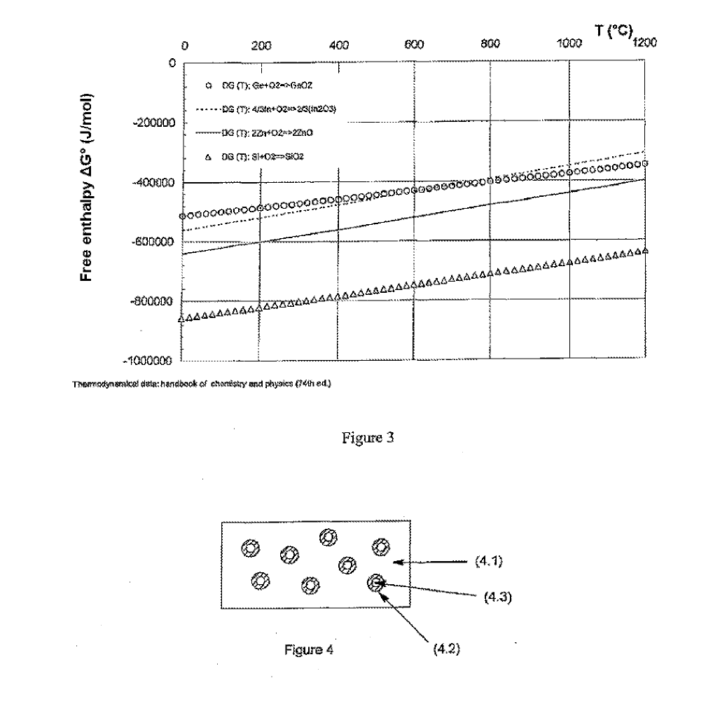

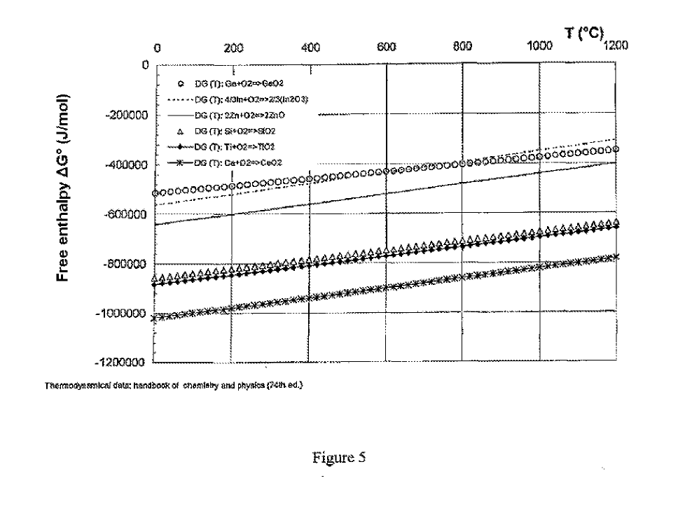

### EXAMPLES

Operating Mode 1:

Direct synthesis of functionalized silicon nanocrystals followed by an anneal at 100-700° C.

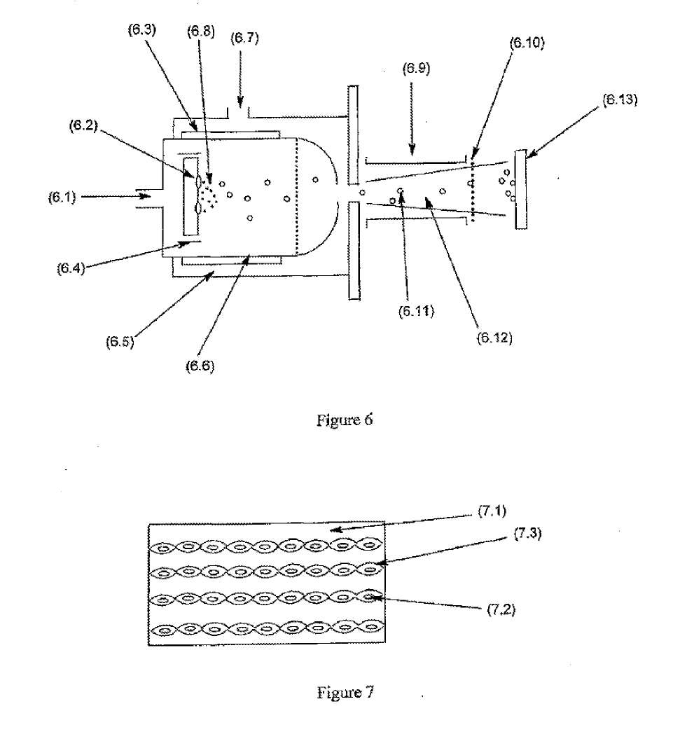

The principle of this operating mode consists in generating, in a nanoparticle source, a binary vapor consisting of silicon atoms and, in a smaller amount, Ti and/or Ce atoms. This vapor may be produced by co-evaporation or co-sputtering of two separate sources, a silicon source and a Ti (and/or Ce) source, or by simply evaporating or sputtering a source made of two or three elements (Si+Ti, Si+Ce and Si+Ti+Ce). The atoms are then condensed from the gaseous phase by cooling the vapor, and the nanoparticles thus formed are transferred into the adjoining deposition chamber in order to be sprayed onto the substrate to be treated. An example of a nanoparticle source operating by sputtering is illustrated in FIG. 6.

In FIG. 6 a stream (6.12) of nanoparticles (6.11) is deposited on a substrate (6.13). The source comprises a vacuum chamber (6.6) into which a plasma gas (6.1) is introduced. This gas ionizes at the surface of the target (6.2) when a DC voltage is applied between (6.2) and (6.4), as for a conventional magnetron cathode. The ions thus formed are accelerated toward the target (6.2) and sputter it, creating in return the vapor (6.8), the latter having a composition that is identical to that of the target. Because the walls of the chamber (6.3) are cooled by flowing water (6.6), this vapor condenses and forms nanoparticles that get progressively larger as they travel toward the outlet of the source under the effect of the vacuum created by pumping (6.7) the outer chamber (6.5). In the chamber (6.5), the pressure is typically about 1×10⁻⁴ mbar whereas that in the chamber (6.6) is about 1×10⁻¹ mbar. The operation of this type of source is described in detail in the article by E. Quesnel et al., Journal of Applied Physics, 107, 4, (2010), p 054309.

If the atmosphere in the deposition chamber is slightly oxidizing, the nanoparticles have a tendency to oxidize. As titanium or cerium reacts more strongly with oxygen than silicon, a superficial layer of Ti or Ce oxide forms. This technique allows very small particles to be deposited, typically having a diameter of between 1 and 10 nm. Under the synthesis conditions used, the nanoparticles are generally amorphous, but due to their small size they can be recrystallized by annealing at a temperature of 700° C. or less. To form the final nanocomposite comprising the silicon nanocrystals embedded in a semiconductor or insulating matrix, both are deposited at the same time or in alternation in the same vacuum deposition chamber.

This original technical solution allows better control of the size of the nanoparticles.

### Example 1a

Direct synthesis of functionalized germanium nanocrystals annealed at 400-500° C.

The process is the same as that described above for example 1 but with Si replaced by Ge.

### Example 2

ZnO/Ti/Si/Ti/ZnO multilayer annealed between 800 and 1000° C. (FIG. 7).

This is, this time, a more conventional method comprising alternate deposition of very thin films: [ZnO (3 nm)/Ti (1 nm)/Si (3 nm)/Ti (1 nm)/ZnO (3 nm)] repeated 30 times. For the sake of simplicity, only four film alternations have been shown in FIG. 7. The Ti film has the effect of reducing the atmosphere in the deposition chamber. The basic multilayer is repeated 30 times, thereby producing an absorber that is about 330 nm in thickness.

The anneal causes Si to precipitate in the form of elongate particles the height of which is perfectly controlled. The silicon is protected by oxidation of the titanium and remains in the semiconductor state.

### Example 2a

ZnO/Ti/Ge/Ti/ZnO multilayer annealed between 800 and 1000° C.

The process is the same as that described above for example 2 but with Si replaced by Ge.

### Example 3

As in example 1, a binary vapor is generated in a nanoparticle source, the vapor consisting of silicon atoms. This vapor is produced by evaporating or sputtering Si. The atoms are then condensed from the gaseous phase by cooling the vapor, and the nanoparticles thus formed are transferred to the adjoining deposition chamber and sprayed onto the substrate to be treated.

By way of these silicon nanoparticles, the alternate deposition of very thin films: [ZnO (3 nm)/Ti (1 nm)/Si (3 nm)/Ti (1 nm)/ZnO (3 nm)], is achieved.

The process is finished off with an anneal at a temperature between 100 and 700° C.

Relative to the process of example 2, the size of the nanoparticles is better controlled.

1. A material comprising a matrix made of a transparent semiconductor or insulating material in which core/shell nanoparticles are dispersed, the core of which is made of a semiconductor chosen from the covalent semiconductors Si, Ge and SiGe, and ionic II-VI or III-V semiconductors, and the shell of which is made of a material chosen from the oxides TiO₂ and/or CeO₂.

2. The material as claimed in claim 1, in which the matrix is made of a material chosen from: SiO₂, SiC, SiNₓ (x≦4/3), In₂O₃, ITO and ZnO, whether doped or not.

3. The material as claimed in claim 1, in which the nanoparticles are between 1 and 30 nm in size.

4. The material as claimed in claim 1, in which the nanoparticles each have a core that is between 1 and 25 nm in size.

5. The material as claimed in claim 1, in which the nanoparticles each have a core, these cores all being substantially the same size.

6. The material as claimed in claim 1, in which the core is made of a semiconductor chosen from: Si, Ge, and Si₍₁₋ₓ₎Geₓ, where x is a number and 0.1≦x≦0.9.

7. The material as claimed in claim 1, in which the concentration of nanoparticles in the matrix is between 1×10¹⁶ cm⁻³ and 1×10¹⁹ cm⁻³.

8. An article formed by superposing films of the materials as claimed in claim 1.

9. The article as claimed in claim 8, which comprises 1 to 10 films of the material.

10. The article as claimed in claim 8, in which the superposed films of material all comprise matrices made of the same material.

11. The article as claimed in claim 8, in which the superposed films of material are all based on nanoparticles made from the same materials.

12. A process for manufacturing materials as claimed in claim 1, which comprises the following steps:
producing, in a nanoparticle source, a binary vapor consisting of core atoms and constituent atoms of the shell, i.e. Ti and/or Ce atoms;
forming nanoparticles by condensing the gaseous phase atoms by cooling the vapor;
transferring the nanoparticles thus formed into a deposition chamber;
spraying onto a substrate;
annealing at a temperature ranging from 100° C. to 700° C.; and
depositing the insulator or semiconductor forming the matrix at the same time as or in alternation with the nanoparticles in the same vacuum deposition chamber.

13. A process for fabricating materials as claimed in claim 1, which comprises the following steps:
depositing in alternation very thin, 0.2 to 5 nm-thick, films of material in the following sequence: matrix material/shell material/core material/shell material/matrix material;
repeating the alternate deposition according to the above sequence 10 to 100 times until a material having the desired thickness is obtained; and
annealing at a temperature ranging from 800° C. to 1000° C.

14. A process for manufacturing materials as claimed in claim 1, which comprises the following steps:
producing, in a nanoparticle source, a binary vapor consisting of core atoms;
forming nanoparticles by condensing the gaseous phase atoms by cooling the vapor;
transferring the nanoparticles thus formed into a deposition chamber;
depositing in alternation very thin, 0.2 to 5 nm-thick, films of material in the following sequence: matrix material/shell material/core nanoparticles/shell material/matrix material; and
annealing at a temperature ranging from 100° C. to 700° C.

15. The process as claimed in claim 13, in which the films of material are deposited by a chemical vapor deposition process.

16. The use of a material as claimed in claim 1 in one of the following applications:
manufacturing photovoltaic cells; manufacturing optoelectronic detectors or imagers; and
manufacturing optical and/or magnetic substrates for data storage.

17. The use of an article as claimed in claim 8 in one of the following applications: manufacturing photovoltaic cells; manufacturing optoelectronic detectors or imagers; and manufacturing optical and/or magnetic substrates for data storage.
